(19) United States
(12) Patent Application Publication
(10) Pub. No.: US 2018/0174856 A1
(43) Pub. Date: Jun. 21, 2018

(54) SUBSTRATE PROCESSING DEVICE

(71) Applicant: J.E.T. CO., LTD., Asakuchi-gun, Okayama (JP)

(72) Inventors: Hirofumi SHOMORI, Asakuchi-gun, Okayama (JP); Atsuo KIMURA, Asakuchi-gun, Okayama (JP)

(21) Appl. No.: 15/737,678

(22) PCT Filed: Jun. 14, 2016
(86) PCT No.: PCT/JP2016/067669

§ 371 Date: Dec. 18, 2017

(30) Foreign Application Priority Data
Jun. 19, 2015 (JP) 2015-123893

(51) Int. Cl. H01L 21/306; H01L 21/67

(52) U.S. Cl. CPC H01L 21/30604; H01L 21/67086

(57) ABSTRACT

Provided is a substrate processing device including a processing bath (12) configured to store processing liquid, and to process a plurality of substrates (24) disposed at predetermined intervals, first and second discharge units (14b₁ and 14b₂) including a flow path (14a) in which the processing liquid flows in a thickness direction of the plurality of substrates (12), a plurality of openings (15) formed along the flow path, and leading end surfaces (16₁ and 16₂) closing a leading end of the flow path (14a), and a supply path (18) that is configured to supply the processing liquid to proximal ends (14bₛ and 14bₑ) of the first discharge unit (14b₁) and the second discharge unit (14b₂), and includes a supply port (20), and a length from the supply port (20) to the leading end surface (16₂) of the second discharge unit (14b₂) is substantially equal to a length from the supply port (20) to the leading end surface (16₁) of the first discharge unit (14b₁). The substrate processing device can perform processing with higher uniformity among the substrates.

### TECHNICAL FIELD

The present invention relates to a substrate processing device of a semiconductor wafer or the like.

### BACKGROUND ART

In a manufacturing process of a semiconductor device, for making a substrate surface clean, cleaning processing of processing a substrate using cleaning liquid is performed by removing part of films on the substrate and forming a desired pattern, or removing all of the films. As processing devices that perform such cleaning processing, there are known a single-wafer-type device that cleans substrates one by one, and a batch-type device that cleans a plurality of substrates by soaking the plurality of substrates in processing liquid in a processing bath in a state in which the plurality of substrates are held at predetermined intervals (e.g., Patent Literature 1).

In addition, in a manufacturing process of a semiconductor device, out of a silicon nitride film (Si₃N₄ film) and a silicon dioxide film (SiO₂ film) that are formed on a substrate such as a silicon wafer, the silicon nitride film is often selectively removed through etching performed by cleaning processing. Phosphoric acid (H₃PO₄) aqueous solution is often used as processing liquid for removing the silicon nitride film. Due to its properties, the phosphoric acid aqueous solution etches not only the silicon nitride film but also a slight amount of the silicon dioxide film. Because minute patterns are required of today's semiconductor devices, it becomes important to keep an etching rate constant for controlling an etching amount, and to keep a selection ratio, which is a ratio between respective etching rates of the silicon nitride film and the silicon dioxide film, constant.

### CITATION LIST

### Patent Literature

Patent Literature 1: Japanese Patent No. 3214503

### SUMMARY OF INVENTION

### Technical Problem

Conventional batch-type processing devices have such a problem that, when a plurality of substrates disposed at predetermined intervals is processed, an etching rate of part of the substrates drops. For example, in a case where a conventional batch-type processing device processes a plurality of substrates for removing predetermined films on substrate surfaces, it is confirmed that removal characteristics of the films become non-uniform among the substrates, and it is demanded to uniformize the removal characteristics among the plurality of substrates in the batch-type processing device.

In view of the foregoing, the object of the present invention is to provide a substrate processing device that can perform, on a plurality of substrates disposed at predetermined intervals, processing with higher uniformity among the substrates.

### Solution to Problem

A substrate processing device according to the present invention includes a processing bath configured to store processing liquid, and to process a plurality of substrates disposed at predetermined intervals, first and second discharge units, each including a flow path in which the processing liquid flows in a thickness direction of the plurality of substrates, a plurality of openings formed along the flow path, and leading end surface closing a leading end of the flow path, and a supply path that is configured to supply the processing liquid to proximal ends of the first discharge unit and the second discharge unit, and includes a supply port, and a length from the supply port to the leading end surface of the second discharge unit is substantially equal to a length from the supply port to the leading end surface of the first discharge unit.

### Advantageous Effects of Invention

According to the present invention, because the substrate processing device includes the first discharge unit and the second discharge unit that have substantially-equal lengths from the supply port to the leading end surfaces, the processing liquid can be discharged with a more uniform flow amount, from the plurality of openings formed in the first discharge unit and the second discharge unit.

Because the processing liquid is discharged with a more uniform flow amount, from the plurality of openings in the first and second discharge units in which the processing liquid flows in the thickness direction of the plurality of substrates, the substrate processing device of the present invention can perform, on the plurality of substrates disposed at the predetermined intervals, processing with higher uniformity among the substrates.

### BRIEF DESCRIPTION OF DRAWINGS

FIG. 1 is a schematic diagram illustrating a state in which a substrate processing device according to the present embodiment is viewed from a side surface.

FIG. 2 is a schematic diagram illustrating a state in which the substrate processing device according to the present embodiment is viewed from immediately above.

FIG. 3 is a schematic diagram illustrating a discharge unit in the substrate processing device according to the present embodiment.

FIG. 4 is a schematic diagram illustrating a discharge unit in a conventional substrate processing device.

### DESCRIPTION OF EMBODIMENT

An embodiment according to the present invention will be described in detail below with reference to the drawings.

### 1. Overall Configuration

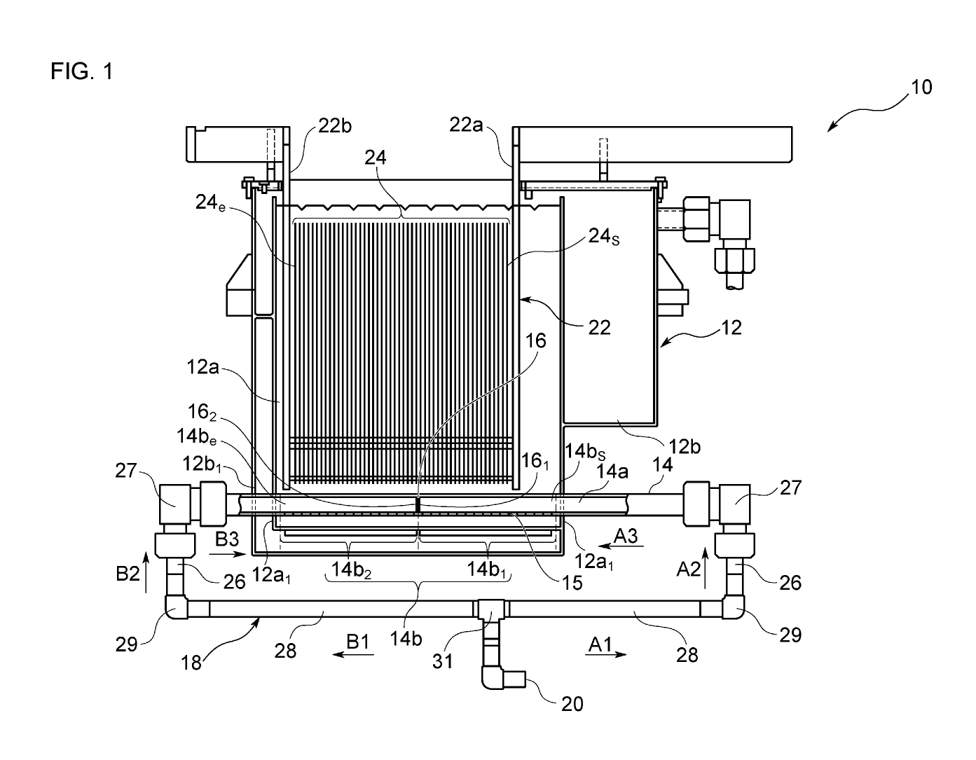

A substrate processing device 10 illustrated in FIG. 1 includes a processing bath 12 including a processing bath main body 12a and an outer bath 12b integrally provided on the outside thereof. The processing bath main body 12a has a box shape having a bottom surface and side surfaces formed integrally with the bottom surface, and has a rectangular upper opening. In the processing bath main body 12a, a pair of surfaces extending in a direction perpendicular to a sheet surface are particularly regarded as side surfaces 12a₁. FIG. 1 illustrates a state in which a plurality of substrates 24 stored in a holder 22 is soaked in processing liquid (not illustrated) in the processing bath main body 12a. The plurality of substrates 24 in this example are semiconductor substrates.

The holder 22 has a plurality of retaining grooves (not illustrated) formed in a direction perpendicular to the sheet surface, over a region from one end 22a to another end 22b. By retaining the substrates 24 in the plurality of respective retaining grooves, the holder 22 stores the plurality of substrates 24 over the region from the one end 22a to the other end 22b. In the present embodiment, the holder 22 can store 50 substrates 24. In this case, a first substrate 24ₛ is retained on one end 22a side of the holder 22, and a 50th substrate 24ₑ is retained on another end 22b side. The side surfaces 12a₁ of the processing bath main body 12a are surfaces extending along front surfaces and rear surfaces of the plurality of arrayed substrates 24. The plurality of substrates 24 can be disposed at predetermined intervals with front surfaces facing each other, rear surfaces facing each other, or front surfaces and rear surfaces facing each other.

In a bottom portion of the processing bath 12, a discharge unit 14b in which a plurality of openings 15 for discharging processing liquid is formed is provided along a thickness direction of the plurality of substrates 24. The discharge unit 14b includes a first discharge unit 14b₁ and a second discharge unit 14b₂ separated via a partition wall 16. In the present embodiment, a portion of a straight pipe 14 disposed in the bottom portion with penetrating through predetermined locations of the processing bath 12 that is provided with the openings 15 is used as the discharge unit 14b. The straight pipe 14 penetrates through the pair of facing side surfaces 12a₁ of the processing bath main body 12a, and one side surface 12b₁ of the outer bath 12b that is provided on the outside of one side surface 12a₁.

The partition wall 16 separating the first discharge unit 14b₁ and the second discharge unit 14b₂ is provided inside the straight pipe 14 in a center vicinity between the pair of facing side surfaces 12a₁ in the processing bath main body 12a. The inside of the straight pipe 14 becomes a flow path 14a in which processing liquid flows in the thickness direction of the plurality of substrates 24. In the present embodiment, because the part of the straight pipe 14 is used as the discharge unit 14b, the first discharge unit 14b₁ and the second discharge unit 14b₂ are coaxially-positioned.

The plurality of openings 15 for discharging processing liquid is formed along the flow path 14a, in the discharge unit 14b including the first discharge unit 14b₁ and the second discharge unit 14b₂. The plurality of openings 15 is provided on the surface of the discharge unit 14b so as to link the flow path 14a and the outside. In the present embodiment, the plurality of openings 15 is provided so as to be able to discharge processing liquid toward a bottom surface of the processing bath main body 12a. The plurality of openings 15 is preferably provided linearly with a uniform diameter. A position of each of the plurality of openings 15 is desired to correspond to a portion between two adjacent substrates in the plurality of substrates 24 disposed at the predetermined intervals. In addition, a total area of the plurality of openings 15 in the discharge unit 14b preferably falls within a range from 20% to 28% of a cross-sectional area of the straight pipe 14. Here, “falls within a range from 20% to 28%” means that, in a case where a total area of the plurality of openings 15 in the discharge unit 14b is denoted by S1, and a cross-sectional area of the straight pipe 14 is denoted by S2, a value represented by (S1/S2)×100(%) falls within a range from 20% to 28%. The diameter and the number of the plurality of openings 15 can be appropriately set considering an inner diameter of the straight pipe 14. For example, in a case where an inner diameter of the straight pipe 14 is about 18 mm, about 63 openings 15 each having a diameter of about 1.2 mm can be formed.

In the partition wall 16 separating the first discharge unit 14b₁ and the second discharge unit 14b₂, a surface 16₁ on the first discharge unit 14b₁ side corresponds to a leading end surface closing a leading end of the flow path 14a in the first discharge unit 14b₁. On the other hand, a surface 16₂ on the second discharge unit 14b₂ side of the partition wall 16 corresponds to a leading end surface closing a leading end of the flow path 14a in the second discharge unit 14b₂. In the present embodiment, the leading end surface 16₁ of the first discharge unit 14b₁ and the leading end surface 16₂ of the second discharge unit 14b₂ are integrally provided by the partition wall 16. As mentioned above, the partition wall 16 is provided inside the straight pipe 14 in the center vicinity between the pair of facing side surfaces 12a₁ in the processing bath main body 12a. Nevertheless, a position of the partition wall 16 needs not always correspond to the center of the plurality of substrates 24 disposed at the predetermined intervals.

Straight pipes 26 are respectively connected to both ends of the straight pipe 14 via L-shaped connecting pipes 27. Straight pipes 28 are respectively connected to end portions of the respective straight pipes 26 via L-shaped connecting pipes 29. The two straight pipes 28 are linearly connected by a T-shaped connecting pipe 31, and a supply port 20 is provided via a remaining portion of the T-shaped connecting pipe 31. Inner diameters of the straight pipes 26 and 28 are preferably equal to an inner diameter of the straight pipe 14. In the present embodiment, a portion of the straight pipe 14 that is obtained by excluding the discharge unit 14b, the two straight pipes 26 connected to the both ends of the straight pipe 14 by the L-shaped connecting pipes 27, and the two straight pipes 28 connected to the respective straight pipes 26 by the L-shaped connecting pipes 29, and connected to each other by the T-shaped connecting pipe 31 form a supply path 18. By such a supply path 18, processing liquid is supplied from the supply port 20 to a first proximal end 14bₛ of the first discharge unit 14b₁ and a second proximal end 14bₑ of the second discharge unit 14b₂.

The first proximal end 14bₛ of the first discharge unit 14b₁ and the second proximal end 14bₑ of the second discharge unit 14b₂ are respective vicinity regions of the pair of facing side surfaces 12a₁ in the processing bath main body 12a. The first proximal end 14bₛ of the first discharge unit 14b₁ is on the first substrate 24ₛ side of a plurality of (50 in the present embodiment) substrates disposed at the predetermined intervals. On the other hand, the second proximal end 14bₑ of the second discharge unit 14b₂ is on the 50th substrate 24ₑ side of the plurality of substrates disposed in this manner.

In the present embodiment, a length from the supply port 20 to the leading end surface 16₁ of the first discharge unit 14b₁, and a length from the supply port 20 to the leading end surface 16₂ of the second discharge unit 14b₂ are substantially equal. In other words, a distance from the supply port 20 to the partition wall 16 via the first discharge unit 14b₁, and a distance from the supply port 20 to the partition wall 16 via the second discharge unit 14b₂ are substantially equal. Here, “substantially equal” means that, in a case where a length from the supply port 20 to the leading end surface 16₁ of the first discharge unit 14b₁ is denoted by D1, and a length from the supply port 20 to the leading end surface 16₂ of the second discharge unit 14b₂ is denoted by D2, a value represented by (D1−D2)/D1×100(%) is equal to or smaller than ±3(%). As long as this condition is satisfied, lengths of the straight pipes 26 and 28 forming the supply path 18 are not especially limited, and can be appropriately set. In a similar manner, the length of the straight pipe 14 forming the discharge unit 14b is not especially limited, either. Nevertheless, if straight pipe portions including the straight pipes 14, 26, and 28 are longer, a rectifying effect in the supply path 18 is enhanced. The entire length of the straight pipe portions can be set to about 35 to 55 times of an inner diameter of the straight pipes, for example.

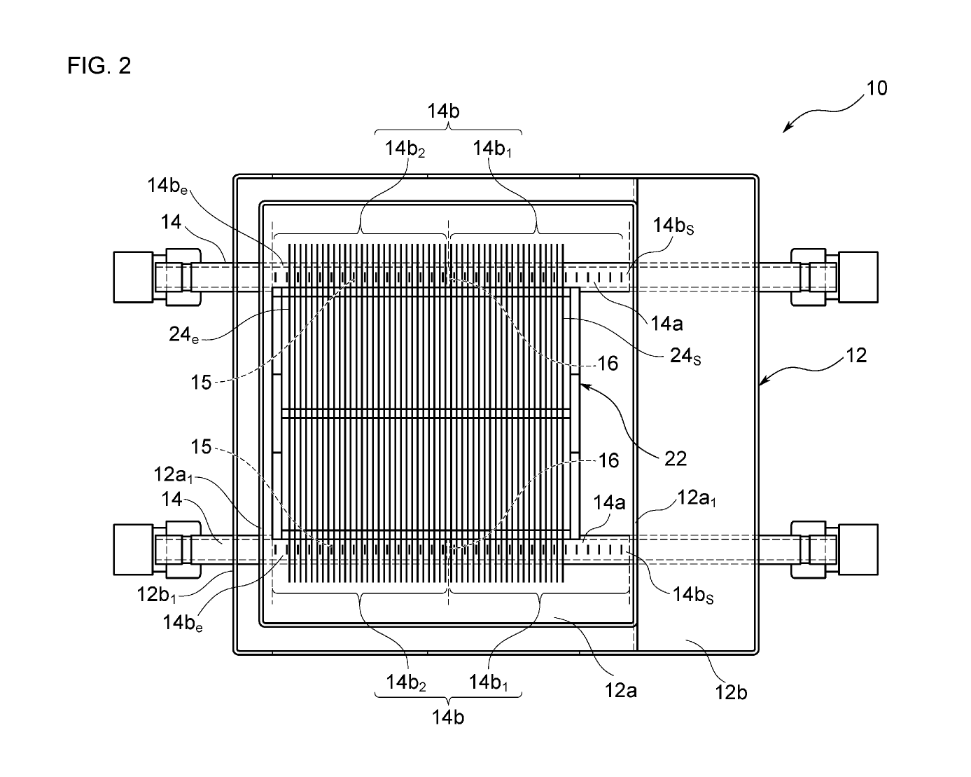

In addition, as illustrated in FIG. 2, in the present embodiment, discharge units 14b each including the first discharge unit 14b₁ and the second discharge unit 14b₂ separated via the partition wall 16 are provided at two locations in the bottom portion of the processing bath 12 along the thickness direction of the plurality of substrates 24 disposed at the predetermined intervals. Each of the discharge units 14b provided at the two locations is formed by the part of the straight pipe 14 as mentioned above.

In the substrate processing device 10, etching removal of silicon nitride films on the surfaces of the plurality of substrates 24 disposed at the predetermined intervals can be performed using, for example, phosphoric acid as processing liquid.

### 2. Movement and Effect

In the substrate processing device 10 of the present embodiment, part of processing liquid supplied from the supply port 20 flows in the supply path 18 as indicated by arrows A1, A2, and A3, and flows into the first discharge unit 14b₁ from the first proximal end 14bₛ of the first discharge unit 14b₁. The remaining part of the processing liquid supplied from the supply port 20 flows in the supply path 18 as indicated by arrows B1, B2, and B3, and flows into the second discharge unit 14b₂ from the second proximal end 14bₑ of the second discharge unit 14b₂. Because the first discharge unit 14b₁ and the second discharge unit 14b₂ are separated by the partition wall 16, in the substrate processing device 10, the processing liquid supplied from the supply port 20 flows in the supply path 18 in two directions toward the partition wall 16.

The front surface and rear surface 16₁ and 16₂ of the partition wall 16 separating the first discharge unit 14b₁ and the second discharge unit 14b₂ correspond to the leading end surfaces closing the leading end of the flow path 14a in the respective discharge units 14b₁ and 14b₂. In the substrate processing device 10 of the present embodiment, the length from the supply port 20 to the leading end surface 16₁ of the first discharge unit 14b₁, and the length from the supply port 20 to the leading end surface 16₂ of the second discharge unit 14b₂ are substantially equal. Substantially-equal amounts of processing liquid flows into the first discharge unit 14b₁ and the second discharge unit 14b₂.

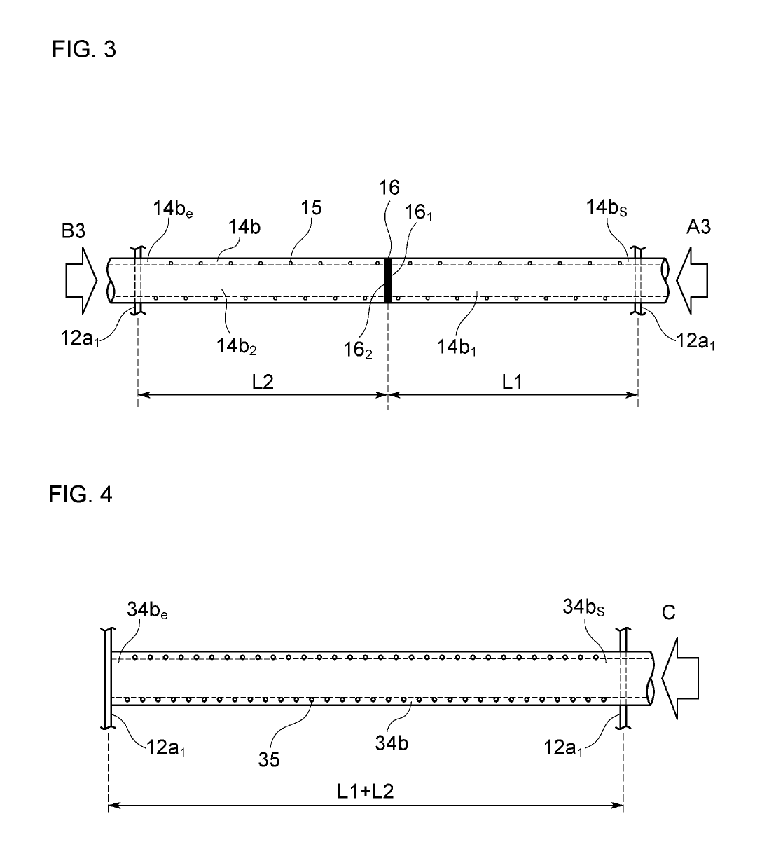

In the first discharge unit 14b₁, because the leading end of the flow path is closed by the leading end surface 16₁, a distance for which the processing liquid flows becomes a distance L1 from the first proximal end 14bₛ to the leading end surface 16₁ as illustrated in FIG. 3. Similarly in the second discharge unit 14b₂, because the leading end of the flow path is closed by the leading end surface 16₂, a distance for which the processing liquid flows becomes a distance L2 from the second proximal end 14bₑ to the leading end surface 16₂ (FIG. 3).

In the present embodiment, because the discharge unit 14b includes the first and second discharge units 14b₁ and 14b₂ separated via the partition wall 16, a distance (L1+L2) for which the processing liquid flows is divided into two. In the first discharge unit 14b₁, processing liquid that has flowed into from the first proximal end 14bₛ flows for the distance L1 in the first discharge unit 14b₁. In the second discharge unit 14b₂, processing liquid that has flowed into from the second proximal end 14bₑ flows for the distance L2 in the second discharge unit 14b₂. As compared with a one-direction flow over the all routes of the distance (L1+L2), in each of the discharge units 14b₁ and 14b₂, the processing liquid flows for the short distance L1 or L2.

In each of the first discharge unit 14b₁ and the second discharge unit 14b₂, because a distance for which processing liquid flows is short, a variation in pressure of the processing liquid flowing inside is reduced. The pressure of the processing liquid flowing inside the first discharge unit 14b₁ and the second discharge unit 14b₂ is more likely to become uniform than that in a case where processing liquid flows for a long distance. In the first discharge unit 14b₁, the processing liquid that has flowed into from the first proximal end 14bₛ flows for the distance L1 at more uniform pressure, to reach the leading end surface 16₁. As a result, the processing liquid is discharged with a more uniform flow amount, from the plurality of openings 15 in the first discharge unit 14b₁. Similarly in the second discharge unit 14b₂, the processing liquid that has flowed into from the second proximal end 14bₑ flows for the distance L2 at more uniform pressure, to reach the leading end surface 16₂. Thus, the processing liquid is discharged with a more uniform flow amount, also from the plurality of openings 15 in the second discharge unit 14b₂.

Moreover, as mentioned above, the length from the supply port 20 to the leading end surface 16₁ of the first discharge unit 14b₁, and the length from the supply port 20 to the leading end surface 16₂ of the second discharge unit 14b₂ are substantially equal. With such a configuration, substantially-equal flow amounts of processing liquid flows into the first discharge unit 14b₁ and the second discharge unit 14b₂. A difference is not generated between the pressure of the processing liquid flowing inside the first discharge unit 14b₁, and the pressure of the processing liquid flowing inside the second discharge unit 14b₂, and the pressures of the processing liquid in the two discharge units 14b₁ and 14b₂ can be made substantially equal.

In this manner, in all regions of the discharge unit 14b including the first discharge unit 14b₁ and the second discharge unit 14b₂, the pressure of the processing liquid flowing inside becomes more uniform. Thus, the processing liquid is discharged with a more uniform flow amount, from all the openings 15 in the discharge unit 14b. As mentioned above, the first proximal end 14bₛ of the first discharge unit 14b₁ is on the first substrate 24ₛ side, and the second proximal end 14bₑ of the second discharge unit 14b₂ is on the 50th substrate 24ₑ side. Thus, throughout all regions of the plurality of substrates 24 disposed at the predetermined intervals, the processing liquid with a more uniform flow amount is discharged from the plurality of openings 15 of the discharge unit 14b.

As a result, it has become possible for the substrate processing device 10 of the present embodiment to perform, on the plurality of substrates 24 disposed at the predetermined intervals, processing with higher uniformity among the substrates.

In a discharge unit of a conventional substrate processing device, throughout all regions in a thickness direction of a plurality of substrates disposed at predetermined intervals, processing liquid is not discharged with a uniform flow amount. As illustrated in FIG. 4, in a discharge unit 34b in a conventional substrate processing device, processing liquid flows into from a first substrate side 34bₛ as indicated by an arrow C. For processing all substrates by discharging processing liquid from openings 35, the processing liquid flows in one direction over the all routes of the distance (L1+L2) in the discharge unit 34b from the first substrate side 34bₛ to a 50th substrate side 34bₑ.

In the conventional substrate processing device, a distance for which the processing liquid flows in the discharge unit 34b provided with the openings 35 is longer than that in the case of the present embodiment. Thus, the pressure of the processing liquid flowing inside the discharge unit 34b varies while the processing liquid flows for the distance (L1+L2). In the discharge unit 34b, throughout a region from the first substrate side 34bₛ to the 50th substrate side 34bₑ, flow amounts of processing liquid discharged from the plurality of openings 35 do not become uniform.

In the conventional substrate processing device, processing liquid is not discharged with a uniform flow amount throughout all regions in the thickness direction of the plurality of substrates disposed at the predetermined intervals. Thus, processing with high uniformity among the substrates cannot be performed on the plurality of substrates disposed at the predetermined intervals.

In contrast to this, in the substrate processing device 10 of the present embodiment, the discharge unit 14b having the plurality of openings 15 for discharging processing liquid includes the two discharge unit 14b₁ and 14b₂ having substantially-equal lengths from the supply port 20 to the leading end surfaces 16₁ and 16₂. Thus, processing liquid can be discharged with a more uniform flow amount, from the plurality of openings 15. As a result, it has become possible for the substrate processing device 10 of the present embodiment to perform, on a plurality of substrates disposed at predetermined intervals, processing with higher uniformity among the substrates.

### 3. Modified Example

The present invention is not limited to the above-described embodiment, and can be appropriately modified without departing from the scope of the spirit of the present invention.

In the above-described embodiment, the part of the straight pipe 14 disposed in the bottom portion of the processing bath main body 12a with penetrating through the pair of facing side surfaces 12a₁ of the processing bath main body 12a that extends along the surfaces of the plurality of substrates 24 is used as the discharge unit 14b. The discharge unit 14b, however, is not limited to this. In the processing bath main body 12a, the L-shaped connecting pipes 27 may be connected to both ends of the straight pipe 24, and the supply path 18 penetrating through side surfaces of the processing bath main body 12a that extend along the thickness direction of the plurality of substrates 24 may be provided. Alternatively, the supply path 18 penetrating through the bottom surface of the processing bath main body 12a can be provided. Depending on the cases, a configuration in which the entire supply path 18 is disposed inside the processing bath main body 12a, and the supply port 20 is provided on the outside of the processing bath main body 12a can be employed.

In addition, in the above-described embodiment, the discharge unit 14b and the supply path 18 form an endless pipe, and the supply path 18 is provided with one supply port 20. The configuration, however, is not always limited to the endless pipe. Separate supply ports 20 may be respectively provided in the first discharge unit 14b₁ and the second discharge unit 14b₂ as long as lengths from the supply ports 20 to the respective leading end surfaces are equal, and processing liquid can be supplied under equal conditions.

The first discharge unit 14b₁ and the second discharge unit 14b₂ need not be part of the same straight pipe. For example, the first discharge unit 14b₁ and the second discharge unit 14b₂ can be separately formed using two cylindrical members each having end surfaces one of which is closed.

The openings 15 formed in the discharge unit 14b including the first discharge unit 14b₁ and the second discharge unit 14b₂ can be provided so as to be able to discharge processing liquid upward. In this case, a direction in which the processing liquid is discharged may be any of the plurality of substrates 24 side and a side surface side of the processing bath main body 12. A line of the plurality of linearly-provided openings 15 is not limited to one line, and a plurality of lines can be provided.

The supply path 18 may have a curved portion. The supply path 18 having the curved portion can be formed as an endless pipe by connecting a curved pipe using a predetermined connecting pipe, for example. Alternatively, the supply path 18 having a curved portion including the supply port 20 may be provided for each of the first discharge unit 14b₁ and the second discharge unit 14b₂.

The substrate processing device of the present invention can process the plurality of substrates 24 disposed at the predetermined intervals, using arbitrary processing liquid. As the description has been given of the substrate processing device 10 of the above-described embodiment, as long as a flow path in which processing liquid flows in the thickness direction of the plurality of substrates 24 is included, the first and second discharge units 14b₁ and 14b₂ in which the plurality of openings 15 for discharging processing liquid is formed are included, and a length from the supply port 20 to the leading end surface 16₁ of the first discharge unit 14b₁, and a length from the supply port 20 to the leading end surface 16₂ of the second discharge unit 14b₂ are substantially equal, processing with higher uniformity among the substrates 24 can be performed on the plurality of substrates disposed at the predetermined intervals.

### REFERENCE SIGNS LIST

10 substrate processing device

12 processing bath

12a processing bath main body

12b outer bath

14, 26, 28 straight pipe

14b, 34b discharge unit

14b₁ first discharge unit

14b₂ second discharge unit

14bₛ first proximal end

14bₑ second proximal end

15, 35 opening

16 partition wall

16₁, 16₂ leading end surface

18 supply path

20 supply port

22 holder

24 a plurality of substrates

27, 29 L-shaped connecting pipe

31 T-shaped connecting pipe

1. A substrate processing device comprising:
a processing bath configured to store processing liquid, and to process a plurality of substrates disposed at predetermined intervals;
first and second discharge units, each including a flow path in which the processing liquid flows in a thickness direction of the plurality of substrates, a plurality of openings formed along the flow path, and leading end surface closing a leading end of the flow path; and
a supply path that is configured to supply the processing liquid to proximal ends of the first discharge unit and the second discharge unit, and includes a supply port,
wherein a length from the supply port to the leading end surface of the second discharge unit is substantially equal to a length from the supply port to the leading end surface of the first discharge unit.

2. The substrate processing device according to claim 1, wherein the second discharge unit is provided coaxially with the first discharge unit.

3. The substrate processing device according to claim 2, wherein the leading end surface of the second discharge unit is provided integrally with the leading end surface of the first discharge unit.

4. The substrate processing device according to claim 1, wherein a total area of the plurality of openings in the first and second discharge units falls within a range from 20% to 28% of a cross-sectional area of the first and second discharge units.
